(19) United States
(12) Patent Application Publication
(10) Pub. No.: US 2008/0246031 A1
(43) Pub. Date: Oct. 9, 2008

(54) PCM pad design for peeling prevention

(76) Inventors: Hao-Yi Tsai, Hsin-Chu City (TW); Shih-Hsun Hsu, Hsin-Chu City (TW); Hsien-Wei Chen, Sinying City (TW); Benson Liu, Taipei City (TW); Chia-Lun Tsai, Hsin-Chu City (TW); Anbiarshy N.F. Wu, Chiayi City (TW)

Correspondence Address: SLATER & MATSIL, L.L.P., 17950 PRESTON ROAD, SUITE 1000, DALLAS, TX, 75252, US

(21) Appl. No.: 11/784,632

(22) Filed: Apr. 9, 2007

(51) Int. Cl. H01L 23/544; H01L 21/66

(52) U.S. Cl. 257/48; 257/620; 257/E23.179; 257/E21.524

(57) ABSTRACT

A semiconductor structure is provided. The semiconductor structure includes a semiconductor chip and a scribe line adjoining the semiconductor chip. A conductive feature is formed in the scribe line and exposed on the surface of the scribe lines, wherein the conductive feature has an edge facing the semiconductor chip. A kerf path is in the scribe line. A first cut is formed in the conductive feature, wherein the first cut extends from the first edge to the kerf path.

### TECHNICAL FIELD

This invention relates to the manufacture of semiconductor chips, and more particularly to the design of process control monitor pads.

### BACKGROUND

Integrated circuit (IC) manufacturers are employing increasingly smaller dimensions and corresponding technologies to make smaller, high-speed semiconductor devices. Along with these advancements, the challenges of maintaining yield and throughput have also increased.

A semiconductor wafer typically includes dies (or chips) separated from each other by scribe lines. Individual chips within the wafer contain circuitry, and the dies are separated by sawing and then are individually packaged. Alternately, the individual chips may be packaged in multi-chip modules. In a semiconductor fabrication process, semiconductor devices on wafers (e.g., an integrated circuit) must be continuously tested at every step of the formation so as to maintain and assure device quality. Usually, a testing circuit is simultaneously fabricated on the wafer along with the actual devices. A typical testing method provides a plurality of test pads (commonly referred to as process control monitor pads, or PCM pads), which are electrically coupled to an external terminal through probe needles, located on the scribe lines. The test pads are selected to test different properties of the wafers, such as threshold voltages, saturation currents, gate oxide thicknesses, and leakage currents.

To place probe needles on the test pads, the test pads typically have dimensions greater than the size of probe needles. As a result, the dimensions of the test pads are typically wider than the kerf for sawing wafers. FIG. 1 illustrates a top view of test pad 12, which is in scribe line 14 between dies 10. Broken lines 16 represent the kerf lines defining the boundaries of the kerf. After the respective wafer is sawed, test pad region 12₁ is destroyed, while test pad residues 12₂ remain un-sawed.

However, circuit failure results from the sawing process. Referring to FIG. 2, test pad residues 12₂ may peel off and shorted to either bonding wire 20 or bump pads 18. Such a failure is random and hard to predict. Although changes in design may possibly solve or reduce the problem, such design changes are limited by several factors. For example, the reduction in the size of test pads 12 may make the test pad residues 12₂ short enough so that they will not reach bonding pad 18 even if the test pad residue peels off. However, the size of test pad 12 is relative to the size of the probe needles, and cannot be reduced as wished as an easy solution for this problem. Another solution to this problem is increasing the distance between the test pads and bonding pads to a degree greater than the width of test pads. However, this solution causes waste of wafer area. A further likely solution is to increase the width of the saw used for sawing wafers, so that no test pad residue is left. However, wider saws cause the decrease in the distance between the saw and seal rings (not shown) in semiconductor chips, and hence the likelihood of damage to the seal ring increases, wherein damage may be caused by the vibration generated in the sawing process. A method is thus needed to solve the above-discussed problem.

### SUMMARY OF THE INVENTION

In accordance with one aspect of the present invention, a semiconductor structure is provided. The semiconductor structure includes a semiconductor chip and a scribe line adjoining the semiconductor chip. A conductive feature is formed in the scribe line and exposed on a surface of the scribe line, wherein the conductive feature has an edge facing the semiconductor chip. A kerf path is in the scribe line. A first cut is formed in the conductive feature, wherein the first cut extends from the first edge to the kerf path.

In accordance with another aspect of the present invention, a semiconductor wafer includes a first and a second semiconductor chip. A scribe line is formed between and adjoining the first and the second semiconductor chips. A process control monitor (PCM) pad is formed in the scribe line. The PCM pad includes a first edge facing the first semiconductor chip; a first cut extending from the first edge toward a center line of the scribe line; a second edge facing the second semiconductor chip; and a second cut extending from the second edge toward the center line.

In accordance with yet another aspect of the present invention, a semiconductor chip includes a first edge; a residue of a scribe line proximate the first edge; a residue of a PCM pad in the residue of the scribe line; and at least one cut separating the residue of the PCM pad into portions.

The present invention has the advantageous features of reduced peeling of PCM residues, and reduced possibility of shortening.

### BRIEF DESCRIPTION OF THE DRAWINGS

For a more complete understanding of the present invention, and the advantages thereof, reference is now made to the following descriptions taken in conjunction with the accompanying drawings, in which:

FIG. 1 illustrates a test pad located between two dies;

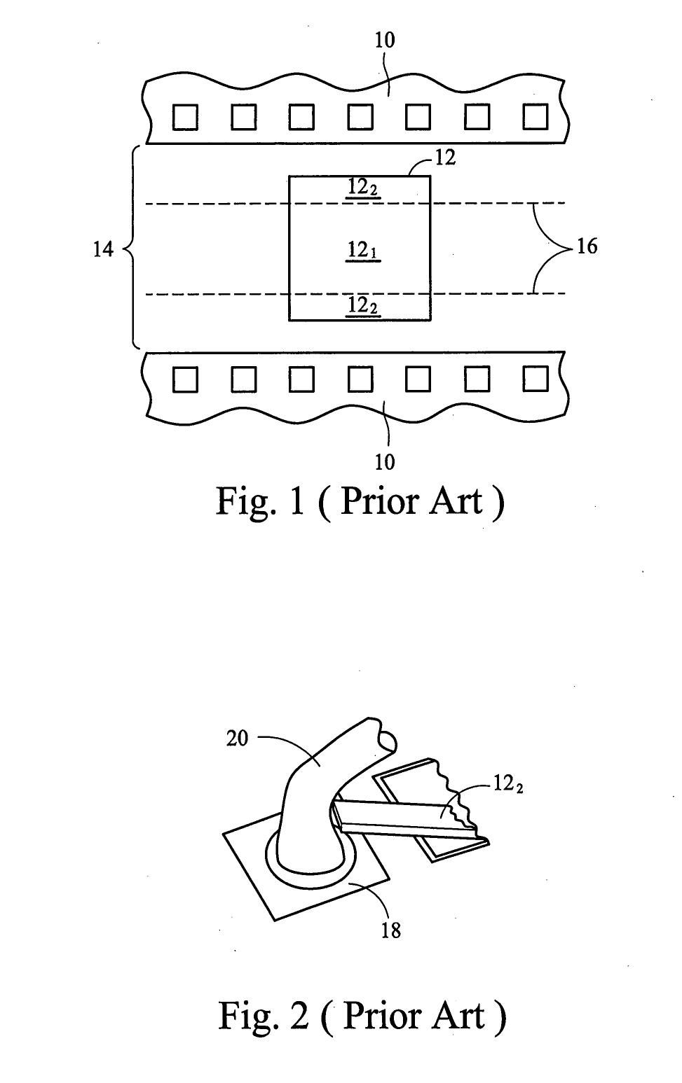

FIG. 2 illustrates a shorting caused by a peeled-off test pad residue;

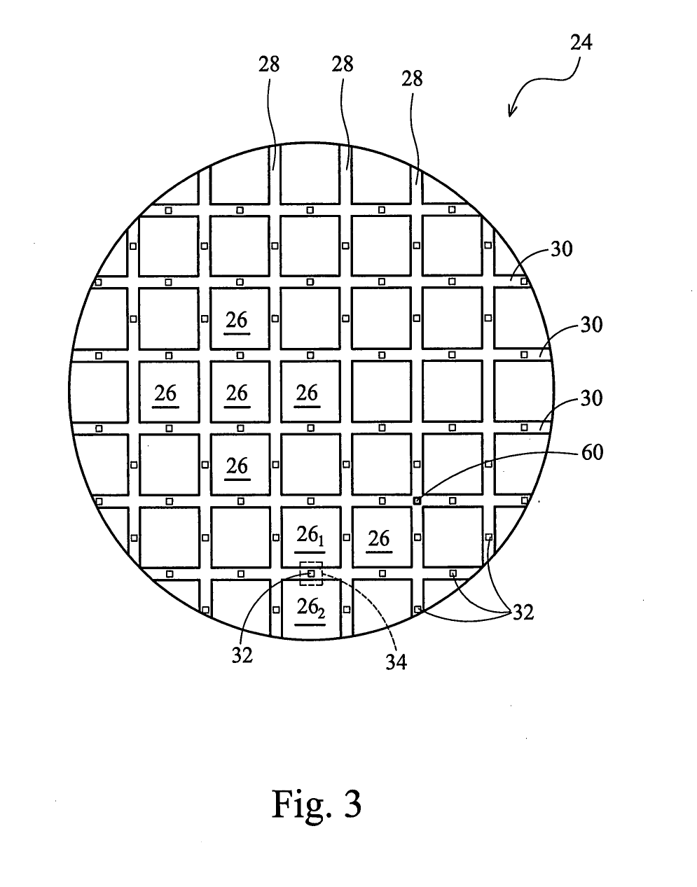

FIG. 3 illustrates a top view of a wafer, which includes scribe lines and test pads within the scribe lines;

FIG. 4 illustrates an embodiment of the present invention, wherein cuts are made in a process control monitor (PCM) pad;

FIG. 5 is a cross-sectional view of the embodiment shown in FIG. 3, wherein the cross-sectional view crosses plane A-A′;

FIGS. 6A and 6B illustrate test pads with different number of cuts; and

FIG. 7 illustrates irregular-shaped cuts in a PCM pad.

### DETAILED DESCRIPTION OF ILLUSTRATIVE EMBODIMENTS

The making and using of the presently preferred embodiments are discussed in detail below. It should be appreciated, however, that the present invention provides many applicable inventive concepts that can be embodied in a wide variety of specific contexts. The specific embodiments discussed are merely illustrative of specific ways to make and use the invention, and do not limit the scope of the invention.

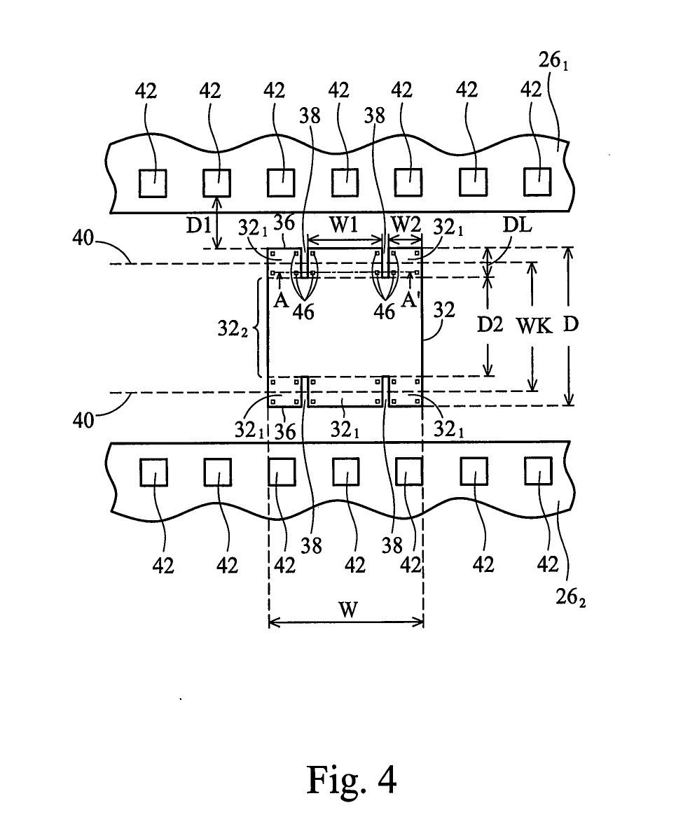

A novel test pad structure and methods of forming the same are provided. Throughout the various views and illustrative embodiments of the present invention, like reference numbers are used to designate like elements. Referring to FIG. 3, a top view of semiconductor wafer 24 is shown. Semiconductor wafer 24 includes chips (also commonly referred to as dies) 26 separated from each other by first scribe lines 28 and second scribe lines 30. The first scribe lines 28 extend along a first direction and the second scribe lines 30 extend along a second direction perpendicular to the first direction. Test pads 32, also referred to as process control monitor (PCM) pads 32, are formed in the first scribe lines 28 and the second scribe lines 30. PCM pads 32 are used in the wafer acceptance test.

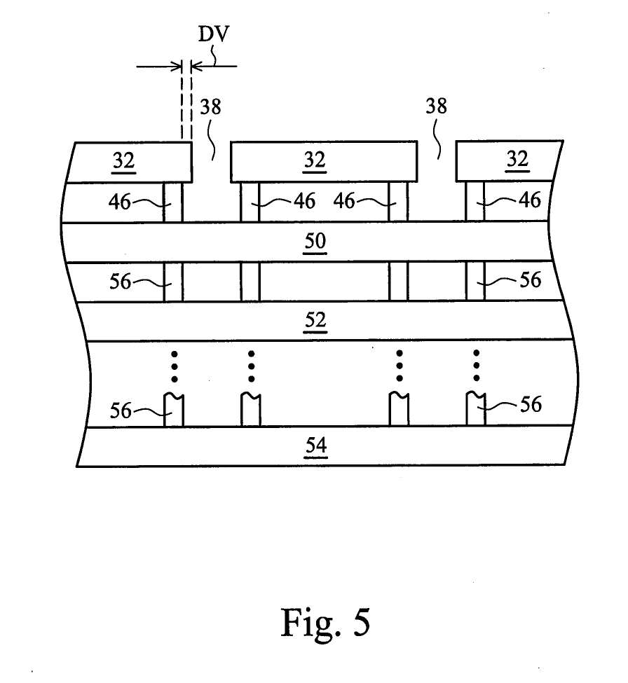

FIG. 4 illustrates the details of a sub region 34 shown in FIG. 3, wherein sub region 34 includes PCM pad 32 between a first semiconductor chip 26₁ and a second semiconductor chip 26₂. Preferably, PCM pad 32 has a rectangular shape, with two edges 36 opposite to each other, and each facing the respective nearest semiconductor chips 26₁ and 26₂. In an exemplary embodiment, PCM pad 32 is an aluminum pad exposed on the top surface of wafer 24. More pads, preferably formed of copper or copper alloys, are formed under, and are connected to PCM pad 32 through vias, wherein more details are provided in subsequent paragraphs.

On each of the edges 36, cuts 38 are formed, hence separating the edge portions of PCM pad 32 into sub regions 32₁. In the subsequent sawing process for sawing semiconductor chips 26 from wafer 24, a saw passes the scribe lines 30 in a kerf path, which is between kerf lines 40. In the preferred embodiment, cuts 38 extend to the nearest kerf line 40. Accordingly, after sawed, sub regions 32₁, which become test pad residues, are separated from each other. In alternative embodiments, cuts 38 further extend beyond the respective kerf lines 40, so that if the kerf path deviates from the desired position, sub regions 32₁ can still be separated. In an exemplary embodiment, cuts 38 extend beyond kerf lines 40 for a distance of about 3 μm or less.

An advantageous feature of the present invention is that by forming cuts 38, widths W1 and W2 of the PCM pad residues 32₁ are less than the width W of PCM pad 32. As one skilled in the art will know, semiconductor chips 26₁ and 26₂ each may include bonding pads 42 for bonding the respective semiconductor chips 26₁ and 26₂, wherein edges 36 each have a vertical distance D1 from the nearest bonding pads 42. In the preferred embodiment, the greater one of widths W1 and W2 is less than the vertical distance D1, so that after wafer 24 is sawed and PCM pad residues 32, peel off, none of the PCM pad residues 32₁ is long enough to reach bonding pads 42. In the more preferred embodiment, widths W1 and W2 of PCM pad 32 are even less than a distance from edges 36 to the nearest seal ring (not shown). In an exemplary embodiment, the greater one of widths W1 and W2 is less than about 5 μm. To achieve optimum effects, cuts 38 on the left half and right half of PCM pad 32 are symmetric relative to a center line (not shown) dividing the left half and the right half. Also, the cuts 38 facing semiconductor chip 26₁ and the cuts 38 facing semiconductor chip 26₂ are preferably symmetric relative to a center line (not shown) between edges 36.

It is to be appreciated that the formation of cuts 38 should not reduce the ability of PCM pad 32 from contacting probe needles in wafer accept tests. Accordingly, sub region 32₂ defined by the tips of cuts 38 is preferably greater than the minimum size required for probing. In an exemplary embodiment, PCM pad 32 has a width W of about 70 μm, and length D, which is the distance between edges 36, of about 50 μm. In an exemplary embodiment, a cantilever probe card, which is typically greater in probe needle size than other commonly used probe cards, is used for probing. Since typical probe marks left by cantilever probe needles only have diameters of about 18 μm, a probe region of about 30 μm×30 μm includes more than a 50 percent margin, and thus is adequate for cantilever probe needles. Length DL of cuts 38 may thus be about 10 μm, so that distance D2 between opposing cuts 38 is about 30 cm. Therefore, sub region 32₂ has an area of about 70 μm×30 μm, which is adequate for the probing.

It is to be realized that the optimum dimensions W1, W2 and DL are related to the subsequent probing process and the sawing process. For example, different types of probing cards require different minimum areas of PCM sub regions 32₂ for probing. The width of kerf may also be different if different saws are used. Accordingly, the dimensions W1, W2 and DL need to be adjusted to ensure not only the peeled-off PCM pad residues 32₁ are not shorted to bonding pads or bonding wires, but also enough PCM area is left for the probing.

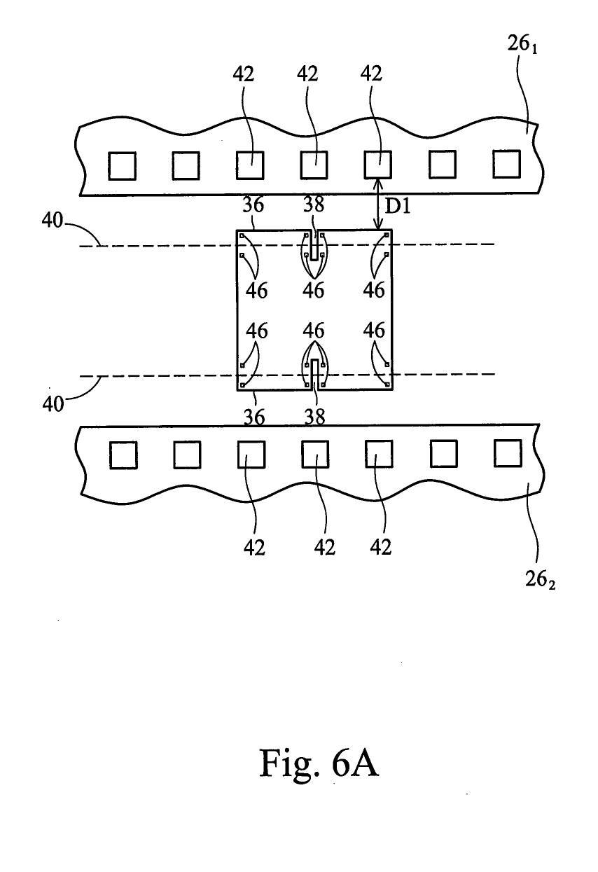

To reduce the peeling of PCM pad residues 32₁, vias 46 are formed on both sides of cuts 38. Vias 46 connect PCM pad 32 and underlying metal pads 50 or metal lines, as is shown in FIG. 5. In an embodiment, the underlying metal pads (or metal lines) 50 are copper pads (or copper lines) formed in the top metallization layer. Metal pads 50 may also be connected to the underlying metal pads or metal lines, such as 52 and 54, through more vias 56. In an exemplary embodiment, metal pads 32, 50, 52 and 54 are vertically aligned, and the connecting vias and metal pads extend from PCM pad 32 to the bottom metallization layer (M1), in which metal pad 54 is located. The connection of PCM pad 32 to the underlying metal pads and metal lines provides an anchoring force, so that in the subsequent sawing process, PCM pad residues 32₁ are less likely to peel off. The distance DV between vias 46 and nearest cuts 38 is preferably small, for example, less than about 0.5 μm. On each side of cuts 38, either a single via or a via group including multiple vias can be formed. Furthermore, vias or via groups are preferably formed adjacent the two edges of PCM pad 32 perpendicular to the kerf path.

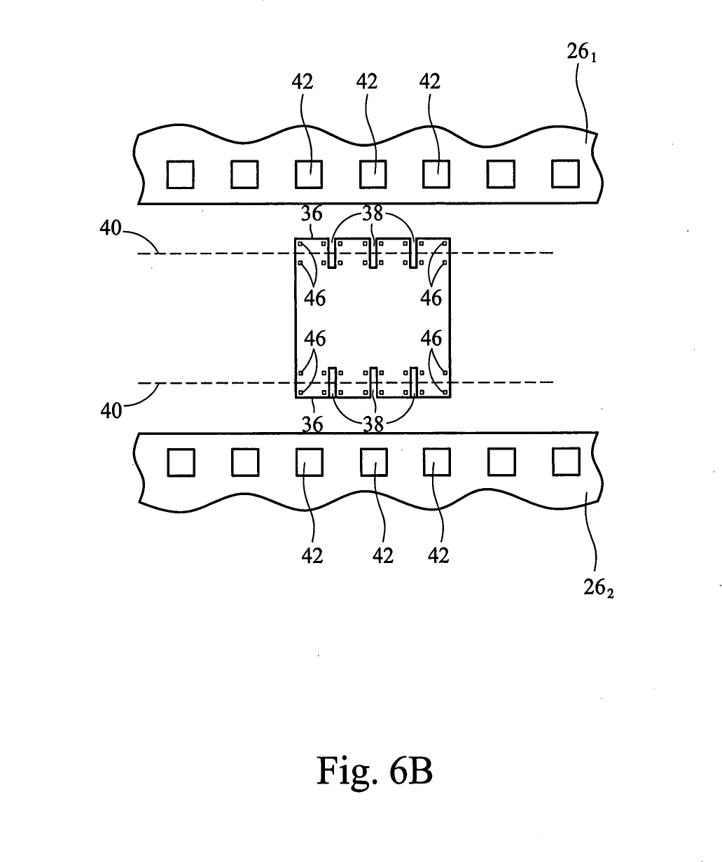

FIGS. 6A and 6B illustrate variations of the preferred embodiment. In FIG. 6A, only one cut 38 is formed extending from each of the edges 36. Cuts 38 are preferably at the center of the respective edges 36. This reduces the length of the possible PCM pad residues 32₁ by a half. Vias 46 are preferably formed on both sides of each of the cuts 38, and are close to cuts 38. Again, in the preferred embodiment, such an embodiment has an optimum effect if a half of width W of PCM pad 32 is less than a vertical distance D1 between edges 36 and the respective nearest bonding pads 42 (refer to FIG. 4).

In FIG. 6B, more than two cuts 38 are formed on each of edges 36 to further reduce the lengths of possible PCM pad residues. Vias 46 are preferably formed close to each of the cuts 38. In both embodiments shown in FIGS. 6A and 6B, cuts 38 preferably extend to, and may extend beyond, kerf lines 40.

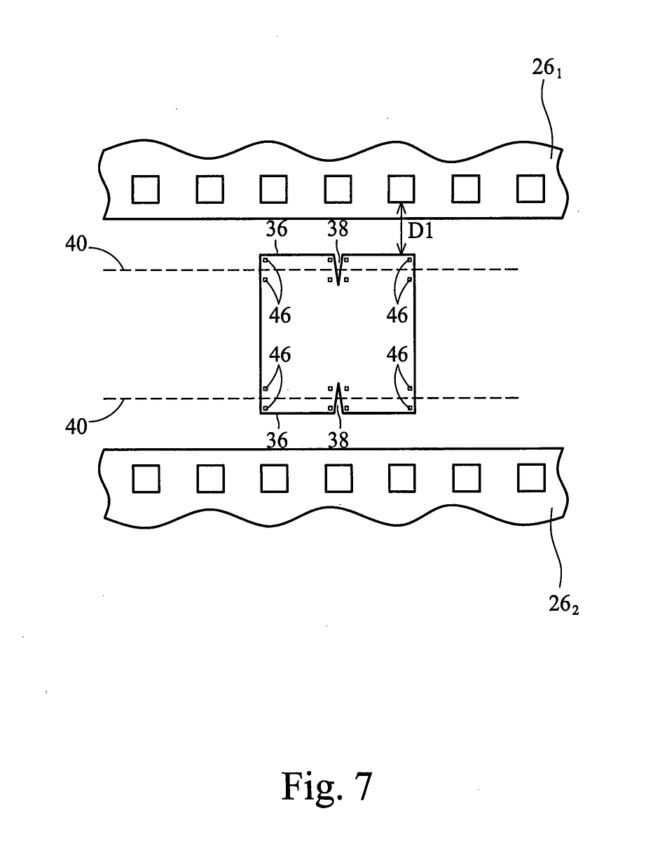

Cuts 38 may have irregular shapes other than the rectangular-shape, provided the cuts have the effect of separating PCM pad residues into shorter portions. FIG. 7 illustrates V-shaped cuts 38. An advantageous feature of the V-shaped cuts 38 is that cuts 38 may extend more beyond kerf lines 40 more without significantly affecting the probing of PCM pad 32, since the tips of the V-shaped cuts 38 are significantly smaller than the respective base portions. Accordingly, even if the kerf path deviates from the desired position, the PCM pad residues 32, can still be separated into shorter portions.

Referring back to FIG. 3, all PCM pads 32 on scribe lines 28 and 30 preferably have cuts similar to the illustrated cuts 38, and cuts 38 in each of the PCM pads 32 preferably face the nearest semiconductor chips 26. Accordingly, cuts 38 of PCM pads 32 on scribe lines 28 face left or right directions, while cuts 38 of PCM pads 32 on scribe lines 30 face up or down directions. If a PCM pad, for example, PCM pad 60, is formed in an intersection region of scribe lines 28 and 30, cuts 38 may need to be formed on all four edges of PCM pad 60, as it cannot be determined which of the scribe lines 28 and 30 are sawed first, and the first sawing may cause the PCM pad residues 32, to peel off, hence the shortening.

It is realized that besides PCM pads, other features, such as frame cells, may have residues after the sawing process. Such residues may also cause shortening problems. The concept of the present invention may thus be applied to these features to reduce the length of the possible peel-off residues.

Although the present invention and its advantages have been described in detail, it should be understood that various changes, substitutions and alterations can be made herein without departing from the spirit and scope of the invention as defined by the appended claims. Moreover, the scope of the present application is not intended to be limited to the particular embodiments of the process, machine, manufacture, and composition of matter, means, methods and steps described in the specification. As one of ordinary skill in the art will readily appreciate from the disclosure of the present invention, processes, machines, manufacture, compositions of matter, means, methods, or steps, presently existing or later to be developed, that perform substantially the same function or achieve substantially the same result as the corresponding embodiments described herein may be utilized according to the present invention. Accordingly, the appended claims are intended to include within their scope such processes, machines, manufacture, compositions of matter, means, methods, or steps.

What is claimed is:

1. A semiconductor structure comprising:
a first semiconductor chip;
a scribe line adjoining the first semiconductor chip;
a conductive feature in the scribe line and exposed on a surface of the scribe line, wherein the conductive feature has a first edge facing the first semiconductor chip;
a kerf path in the scribe line; and
a first cut in the conductive feature, wherein the first cut extends from the first edge to the kerf path.

2. The semiconductor structure of claim 1 further comprising:
a second semiconductor chip on an opposite side of the scribe line than the first semiconductor chip;
a second edge of the conductive feature facing the second semiconductor chip; and
a second cut in the conductive feature, wherein the second cut extends from the second edge to the kerf path.

3. The semiconductor structure of claim 2, wherein the first and the second semiconductor chips are on different sides of a center line of the scribe line, and wherein the first and the second cuts are symmetrical relative to the center line.

4. The semiconductor structure of claim 2 further comprising third cuts extending from the first edge toward a center line of the scribe line, and fourth cuts extending from the second edge toward the center line of the scribe line, wherein all cuts extending from the first edge and all cuts extending from the second edge are symmetrical relative to a center line of the conductive feature, and wherein the center line is perpendicular to a longitudinal direction of the scribe line.

5. The semiconductor structure of claim 1 further comprising a first via and a second via on opposite sides of the first cut, wherein the first and the second vias are close to the first cut, and wherein the first and the second vias are each connected to an underlying metal feature.

6. The semiconductor structure of claim 5 further comprising a first plurality of vias connecting a plurality of metallization layers, and a second plurality of vias connecting the plurality of metallization layers, wherein the first plurality of vias are vertically aligned to the first via, and wherein the second plurality of vias are vertically aligned to the second via.

7. The semiconductor structure of claim 1, wherein the conductive feature is a process control monitor pad.

8. The semiconductor structure of claim 1, wherein the first cut extends from the first edge to within the kerf path.

9. The semiconductor structure of claim 1, wherein the first edge of the conductive feature and a nearest bonding pad on the first semiconductor chip has a distance, and wherein the first cut divides an edge portion of the conductive feature into sub regions, and wherein a longest length of the sub regions is less than the distance.

10. The semiconductor structure of claim 1, wherein the first cut has a shape selected from the group consisting essentially of a rectangular-shape and a V-shape.

11. The semiconductor structure of claim 1, wherein the conductive feature further comprises a second edge perpendicular to a longitudinal direction of the scribe line, and wherein the second edge is free from cuts.

12. A semiconductor wafer comprising:
a first and a second semiconductor chip;
a scribe line between and adjoining the first and the second semiconductor chips; and
a process control monitor (PCM) pad in the scribe line, wherein the PCM pad comprises:
a first edge facing the first semiconductor chip;
a first cut extending from the first edge toward a center line of the scribe line;
a second edge facing the second semiconductor chip; and
a second cut extending from the second edge toward the center line.

13. The semiconductor wafer of claim 12 further comprising:
a plurality of semiconductor chips;
a plurality of scribe lines separating the plurality of semiconductor chips; and
a plurality of PCM pads in the plurality of scribe lines, wherein each of the PCM pads comprises a cut in each of edges facing a nearest semiconductor chip.

14. The semiconductor wafer of claim 13 further comprising an additional PCM pad in an intersection region of two of the plurality of scribe lines, wherein the additional PCM pad comprises cuts on all four edges.

15. The semiconductor wafer of claim 13, wherein for each of the plurality of PCM pads, cuts are only formed on edges parallel to a longitudinal direction of the respective scribe line.

16. The semiconductor wafer of claim 12, wherein the first edge of the conductive feature and a nearest bonding pad on the first semiconductor chip has a distance, and wherein the first cut divides an edge portion of the conductive feature into sub regions, and wherein a longest length of the sub regions is less than the distance.

17. The semiconductor wafer of claim 12, wherein a center region of the PCM pad defined by cuts on the first and the second edges has a size greater than a probe mark of a probe needle for probing the PCM pad.

18. The semiconductor wafer of claim 12 further comprising vias on both sides of, and close to, each of the first and the second cuts, wherein the vias connect the PMC pad to an underlying metal pad.

19. A semiconductor chip comprising:
a first edge;
a residue of a scribe line proximate the first edge;
a residue of a process control monitor (PCM) pad in the residue of the scribe line; and
at least one cut separating the residue of the PCM pad into portions.

20. The semiconductor chip of claim 19 further comprising vias on both sides of, and are close to, each of the at least one cut, wherein the vias connect the residue of the PCM pad to an underlying pad.

21. The semiconductor chip of claim 19, wherein the residue of the PCM pad and a nearest bonding pad on the semiconductor chip has a distance greater than a greatest length of the portions of the residue.

22. The semiconductor chip of claim 21, wherein the greatest length is less than about 5 μm.

23. The semiconductor chip of claim 22 further comprising a second edge, a third edge opposite to the first edge, and a fourth edge opposite to the second edge, and a plurality of PCM pad residues proximate the first, the second, the third and the fourth edges, wherein each of the plurality of PCM pad residues comprises at least one cut separating the respective PCM residue into portions.

24. The semiconductor chip of claim 23, wherein cuts in the plurality of PCM pad residues are symmetric relative to a center line between the first and the third edges, and wherein cuts in the plurality of PCM pads are symmetric relative to a center line between the second and the fourth edges.
